(19) United States
(12) Patent Application Publication
(10) Pub. No.: US 2005/0183986 A1
(43) Pub. Date: Aug. 25, 2005

(54) Fixture for accessing memory cards

(75) Inventor: Chien-Yuan Chen, Banchiau City (TW)

Correspondence Address: TROXELL LAW OFFICE PLLC, SUITE 1404, 5205 LEESBURG PIKE, FALLS CHURCH, VA, 22041, US

(73) Assignee: Power Digital Card Co.

(21) Appl. No.: 11/011,180

(22) Filed: Dec. 15, 2004

(30) Foreign Application Priority Data
Feb. 24, 2004 (TW) 93202617

(51) Int. Cl. H05K 1/00; B65D 85/30

(52) U.S. Cl. 206/713

(57) ABSTRACT

According to the invention, a fixture for memory cards for accessing memory cards includes a main body and a sliding cover. The main body appears as a U-shaped structure; and has sliding grooves at an end portion of the opening and for accomplishing sliding movements and closure of the sliding cover, and one stopping post at one side thereof for offering stopping effects and forming an accommodating chamber with the main body in order to accommodate a memory card. The sliding cover has a protruding strip disposed at a side thereof corresponding with an edge of a memory card. Using the aforesaid structure, memory cards are ensured to be placed in same directions in the main body when accessing the memory cards.

### BACKGROUND OF THE INVENTION

(a) Field of the Invention

The invention relates to a fixture for accessing memory cards, and more particularly, to a fixture capable of storing, and accessing large amounts of memory cards when applied to an operating machine.

(b) Description of the Prior Art

With fast development of information technology, conventional compact discs for mass data storage are gradually being replaced by memory cards that are capable of rapidly accessing and storing mass data. Available memory cards include CF, MD, MMC, SD, MS, XD and SM cards. These memory cards are suitable for storing not only text files but also various graphic files like JPG, MPEG, MPG, and ASF files as well as video files.

With advantages namely being small in size that offer excellent portability, existing memory cards are being extensively applied to computers, digital static cameras, digital video cameras and portable discs. Above all, these memory cards are provided with expanded memory capacities from previous 8 MB to current 16 MB and even up to 156 MB.

Apart from a sensor area for accessing data, a common memory card is generally devised with an edge for facilitating a user to quickly identify and installing the memory card to a device. Yet, memory cards are small in volume, and therefore for manufacturers of this particular industry, it is an imminent issue as how to process large amount inventory and to apply the memory cards for operations on machines.

### SUMMARY OF THE INVENTION

A fixture for memory cards according to the invention comprises a main body and a sliding cover. The main body appears as a U-shaped structure; and has a sliding groove at an end portion of the opening and for accomplishing sliding movements and closure of the sliding cover, and a stopping post at one side thereof for offering stopping effects and forming an accommodating chamber with the main body in order to accommodate memory cards. The sliding cover has a protruding strip disposed at a side thereof corresponding with edges of memory cards to form a protection design.

The primary object is to detect whether memory cards are placed in appropriate directions using the protruding strip and sliding movements of the sliding cover when storing the memory cards, thereby ensuring the memory cards are placed in same directions when stored in the main body.

The secondary object of the invention is to observe a quantity of memory cards in the main body and whether defects at sides are present using peep windows provided at the main body and the sliding cover.

The other object of the invention is to quickly locate and maintain appropriate directions of every main body using a corresponding channel at a side of the main body when placing the main body at an operating machine.

### BRIEF DESCRIPTION OF THE DRAWINGS

FIG. 1 shows an exploded schematic view according to the invention.

FIG. 2 shows a schematic view of an assembly according to the invention.

FIG. 3 shows a side schematic view according to the invention.

FIG. 4 shows a schematic view according to the invention being applied to an operating machine.

### DETAILED DESCRIPTION OF THE PREFERRED EMBODIMENTS

To better understand the contents and achieved effects of the invention, detailed descriptions shall be given with the accompanying drawings below.

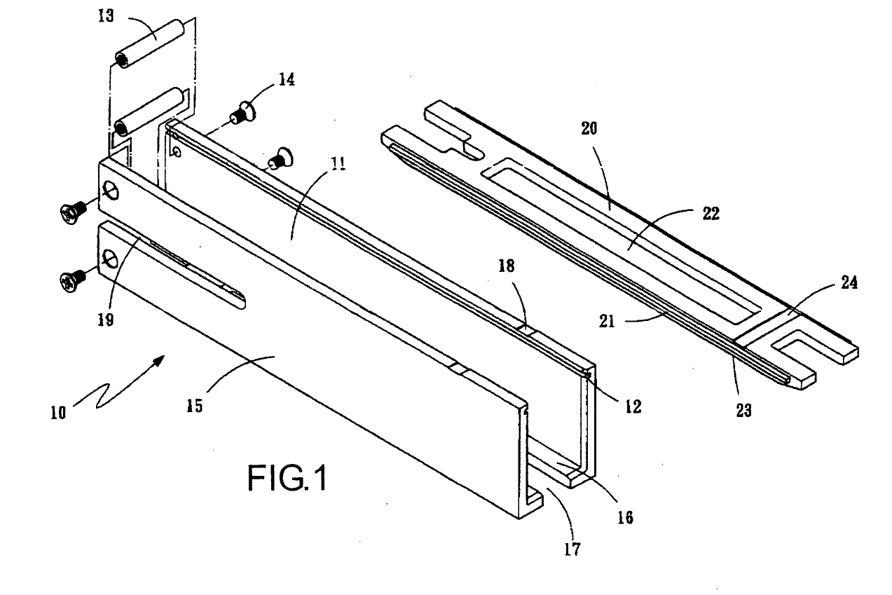

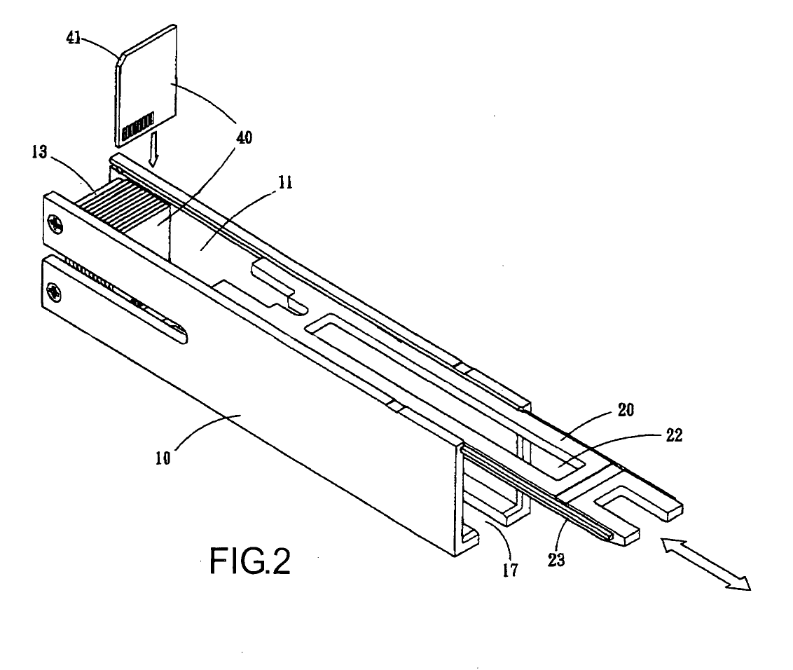

Referring to FIGS. 1 and 2, a memory card fixture according to the invention comprises a main body 10 and a sliding cover 20.

The main body 10 appearing as a U-shaped structure, has an opening 11, sliding grooves 12 at an end portion of the opening 11, at least one stopping post 13 at one side thereof for offering stopping effects, and at least one peep window 16 for corresponding with the opening 11 and disposed at a plate body 16.

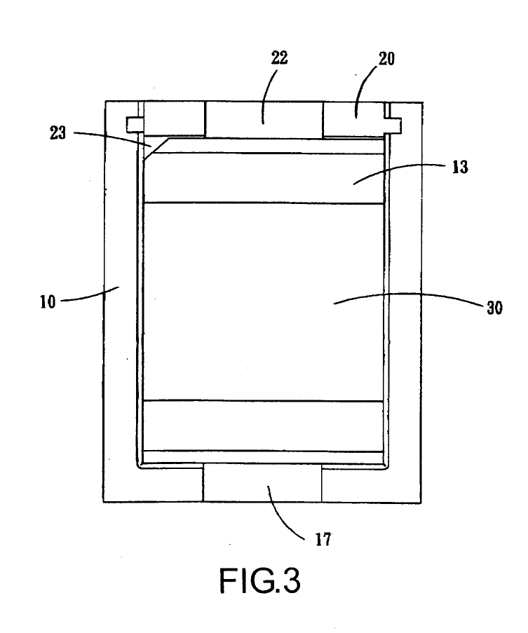

The sliding cover 20 capable of relative sliding movements at the main body 10, has sliding tracks 21 at two sides thereof for corresponding with the sliding grooves 12, such that the sliding cover 20 is allowed to freely slide at the main body 10; and together with the main body 10 forms an accommodating chamber 30 for accommodating memory cards. Referring to FIG. 3, the sliding cover 20 is also provided with a peep window 22 for corresponding with the main body 10, and a protruding strip 23 disposed at a side thereof corresponding with the main body 10 and corresponding with an edge 41 of a memory card 40.

According to the aforesaid structure, the memory card 40 is first placed into the accommodating chamber 30 via the opening 11 and using stopping effects of the stopping post 13, and is then enabled to proceed with sliding movements at the main body 10 using the sliding cover 20. For that the sliding cover 20 has one end thereof that is corresponding with the main body 10 provided with the protruding strip 23, whether a direction of the memory card 40 being placed is appropriate or not is detected using the protection design formed by the protruding strip 23. Meanwhile, by observing through the peep windows 17 and 22, sides of the memory card 40 are inspected to spot defects.

In addition, the main body 10 and the sliding cover 20 are respectively provided with corresponding alignment grooves 18 and 24, so as to effectively orientate directions when the sliding cover 20 is mounted on the main body 10. Thus, by avoid inappropriate installing directions of the sliding cover 20, the sliding cover 20 can be quickly assembled with the main body 10.

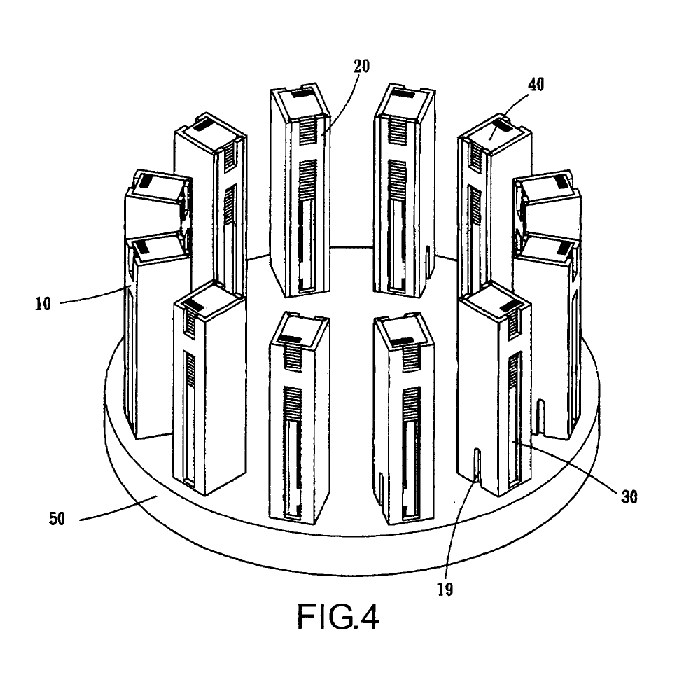

The main body 10 further has a corresponding channel 19. Referring to FIG. 4, when the main body 10 is placed on a machine 50, the corresponding channel 19 is for maintaining appropriate directions of the main body 10. Also, when the main body 10 is placed on the machine 50, one end thereof without the stopping post 13 is placed to face upward, such that the memory card 40 is exposed at an opening of the accommodating chamber 30 formed by the main body 10 and the sliding cover 20. Thus, when the machine 50 uses a machine arm thereof to access the memory card 40, appropriate directions of the memory card 40 can be maintained to promote processing conveniences.

Conclusive from the aforesaid descriptions, the fixture for accessing memory cards according to the invention, using the accommodating chamber 30 formed by the main body 10 and the sliding cover 20, large amounts of memory card inventory can be stored. In addition, using the protruding strip 23 that maintains appropriate directions of the memory card 40 being stored, and the provision of the corresponding channel 19, not only the main body 10 is maintained in appropriate directions when placed on the machine 10, but also the memory card 40 is accessed in appropriate directions when the machine 50 accesses the memory card 40 using a machine arm thereof, thereby promoting processing conveniences.

It is of course to be understood that the embodiment described herein is merely illustrative of the principles of the invention and that a wide variety of modifications thereto may be effected by persons skilled in the art without departing from the spirit and scope of the invention as set forth in the following claims.

1. A fixture for memory cards, comprising:
a main body appearing as a U-shaped structure; and has an opening, sliding grooves at an end portion of the opening, and a stopping post at one side thereof; and
a sliding cover having sliding tracks for corresponding with the sliding grooves, capable of sliding movements at the main body, forming an accommodating chamber, and provided with a protruding strip at one end thereof corresponding with the main body;
thus, a memory card is accommodated in the accommodating chamber, and directions of the memory card placed are observed using the protruding strip and sliding movements of the sliding cover.

2. The fixture for memory cards in accordance with claim 1, wherein corresponding sides of the main body and the sliding cover are respectively provided with peep windows for inspecting the memory card.

3. The fixture for memory cards in accordance with claim 1, wherein the main body and the sliding groove are respectively provided with alignment grooves, thereby effectively identifying directions when the sliding cover is placed on the main body, as well as preventing inappropriate installation directions of the sliding cover to quickly mount the sliding groove at the main body.

4. The fixture for memory cards in accordance with claim 1, wherein the main body is provided with a corresponding channel.
